(19) United States
(12) Patent Application Publication
(10) Pub. No.: US 2026/0136495 A1
(43) Pub. Date: May 14, 2026

(54) HEAT DISSIPATION APPARATUS AND ELECTRONIC DEVICE

(71) Applicant: Luxshare Thermal Technologies (HuiZhou) Co., Ltd, Huizhou City, Guangdong Province (CN)

(72) Inventors: Jun Zhao, Huizhou City (CN); Tao Sun, Huizhou City (CN); Pengfei Wang, Huizhou City (CN); Jianwei Wang, Huizhou City (CN); Ga Zhang, Huizhou City (CN)

(73) Assignee: Luxshare Thermal Technologies (HuiZhou) Co., Ltd, Huizhou City, Guangdong Province (CN)

(21) Appl. No.: 19/374,216

(22) Filed: Oct. 30, 2025

(30) Foreign Application Priority Data
Nov. 12, 2024 (CN) 202411613619.X

(51) Int. Cl. H05K 7/20

(52) U.S. Cl. CPC H05K 7/20272

(57) ABSTRACT

Provided are a heat dissipation apparatus and an electronic device. The heat dissipation apparatus includes a heat dissipation module including at least two first liquid cooling plates arranged side by side and connected in series. Each first liquid cooling plate includes a liquid cooling channel with a liquid inlet and a liquid outlet. The liquid inlet of the first liquid cooling plate at one end is connected to a first liquid inlet pipe, and the liquid outlet or liquid inlet of the first liquid cooling plate at the other end is connected to a first liquid return pipe. For all the other liquid outlets and liquid inlets, two adjacent liquid outlets are connected through a connecting pipe, and two adjacent liquid inlets are connected through another connecting pipe.

### CROSS-REFERENCE TO RELATED APPLICATION

This application claims the benefit of Chinese Patent Application No. 202411613619.X, filed on Nov. 12, 2024, entitled “Heat dissipation apparatus and Electronic device”, which is incorporated herein by reference in its entirety.

### FIELD

The present disclosure relates to the technical field of communication devices, and specifically, to a heat dissipation apparatus and an electronic device.

### BACKGROUND

With the continuous growth of demand for high-density and high-performance optical modules in data centers and high-performance computing fields, heat dissipation has become one of the key factors restricting device performance. Conventional air cooling is inadequate for high-power-density optical modules, while liquid cooling has gradually become the mainstream trend in the industry due to its excellent heat dissipation effect. However, in practical applications, especially in high-density installation environments, a plurality of liquid cooling plates for a plurality of optical modules usually need to be installed closely side by side to maximize the utilization of chassis space.

Currently, adjacent liquid cooling plates are usually connected in series, the liquid inlet and outlet of adjacent liquid cooling plates are connected through a connecting pipe. Due to the small size of optical modules and space-saving requirements, liquid inlets and outlets of liquid cooling plates thereon are often closely arranged, resulting in extremely small bending radius of the connecting pipe between the adjacent cooling plates, thereby increasing installation complexity of the connecting pipe. Meanwhile, the sharp bending angle of the connecting pipe increases hydraulic resistance, degrades cooling efficiency, and causes risks of pipe damage.

### SUMMARY

Embodiments of the present disclosure provide a heat dissipation apparatus and an electronic device.

In one aspect, embodiments of the present disclosure provide a heat dissipation apparatus, including at least one set heat dissipation module. Each heat dissipation module includes at least two first liquid cooling plates arranged side by side and connected in series. Each first liquid cooling plate includes a liquid cooling channel with a liquid inlet and a liquid outlet. The liquid inlet and the liquid outlet are arranged on a first side of the first liquid cooling plate and are close to two side edges respectively. The liquid inlet of one of the at least two first liquid cooling plates is adjacent to the liquid outlet of the an adjacent one of the at least two first liquid cooling plates. The at least two first liquid cooling plates arranged side by side in the heat dissipation module include a first liquid cooling plate at one end and a first liquid cooling plate at the other end. The liquid inlet of the first liquid cooling plate at one end is connected to a first liquid inlet pipe, the liquid outlet or liquid inlet of the first liquid cooling plate at the other end is connected to a first liquid return pipe, and for all other liquid outlets and liquid inlets of the at least two first liquid cooling plates, two adjacent liquid outlets are connected through a connecting pipe, two adjacent liquid inlets are connected through another connecting pipe.

In another aspect, embodiments of the present disclosure provide an electronic device including a chassis and the heat dissipation apparatus as described in the above aspect. At least two optical module groups are arranged in the chassis, and the first liquid cooling plates are connected to the at least two optical module groups in one-to-one correspondence.

### BRIEF DESCRIPTION OF DRAWINGS

The above and other objectives, features, and advantages of the present disclosure will be clearer from the following description of embodiments of the present disclosure with reference to the accompanying drawings.

FIG. 1 is a schematic block diagram of a heat dissipation apparatus according to an embodiment of the present disclosure;

FIG. 2 is a schematic structural diagram showing a first liquid cooling plate, a liquid inlet connector, and a liquid outlet connector in a connected state according to an embodiment of the present disclosure;

FIG. 3 is a schematic structural diagram showing a first liquid cooling plate, a first connection block, and a second connection block in a connected state according to another embodiment of the present disclosure;

FIG. 4 is a schematic structural diagram of a heat dissipation apparatus according to another embodiment of the present disclosure;

FIG. 5 is a schematic structural diagram of a first liquid cooling plate according to another embodiment of the present disclosure;

FIG. 6 is a schematic structural diagram of a first connection block according to another embodiment of the present disclosure;

FIG. 7 is a schematic structural diagram of a second connection block according to another embodiment of the present disclosure;

FIG. 8 is a cross-sectional view of a first liquid cooling plate, a first connection block, and a second connection block in a connected state according to another embodiment of the present disclosure;

FIG. 9 is a schematic structural diagram of a heat dissipation apparatus according to still another embodiment of the present disclosure;

FIG. 10 is a schematic structural diagram of a first liquid cooling plate according to still another embodiment of the present disclosure;

FIG. 11 is a schematic structural diagram of a first connection block according to still another embodiment of the present disclosure;

FIG. 12 is a schematic structural diagram of a second connection block according to still another embodiment of the present disclosure;

FIG. 13 is a cross-sectional view of a first liquid cooling plate, a first connection block, and a second connection block in a connected state according to another embodiment of the present disclosure; and

FIG. 14 is a schematic structural diagram of an electronic device according to an embodiment of the present disclosure.

### DETAILED DESCRIPTION OF THE EMBODIMENTS

The present disclosure is described below based on embodiments, but the present disclosure is not merely limited to these embodiments. In the following detailed description of the present disclosure, some specific details are described. The present disclosure can also be fully understood by those skilled in the art without the description of these details. In order to avoid confusing the essence of the present disclosure, well-known methods, processes, flows, elements, and circuits are not described in detail.

Moreover, those of ordinary skill in the art should understand that the accompanying drawings provided herein are for the purpose of illustration only, and the accompanying drawings are not necessarily drawn to scale.

Unless otherwise specified and limited, the terms “mounted”, “connected”, “connection”, “fixed”, and the like should be understood in a broad sense. For example, the “connection” may be fixed connection, detachable connection, integration, mechanical connection, electrical connection, direct connection, indirect connection by a medium, internal communication of two elements, or interaction between two elements. Those of ordinary skill in the art can understand the specific meanings of the above terms in the present disclosure according to specific circumstances.

Unless explicitly required by the context, the terms such as “include” and “contain” in the entire application document should be interpreted as including rather than exclusive or exhaustive, that is, “include but not limited to”.

In the description of the present disclosure, it should be understood that the terms “first”, “second”, etc. are only used for descriptive purposes and cannot be understood as indicating or implying relative importance. Moreover, in the description of the present disclosure, unless otherwise stated, “a plurality of” means two or more.

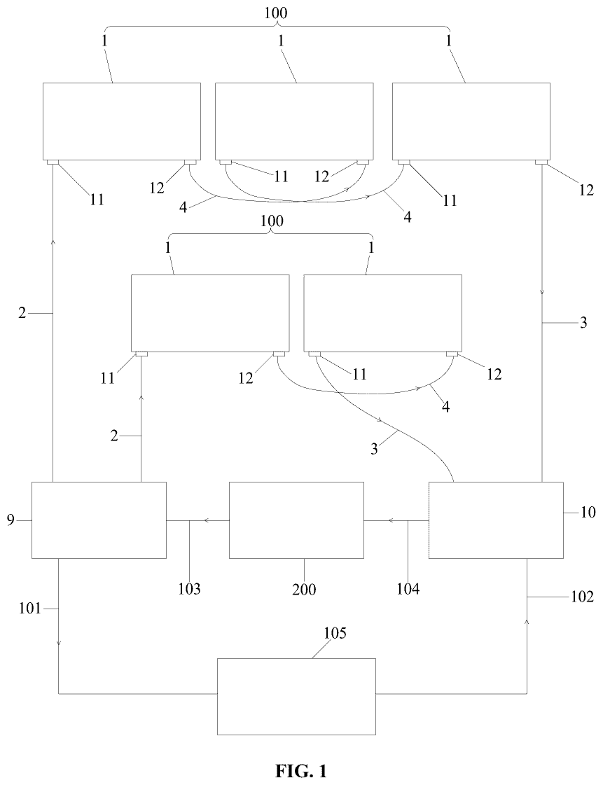

FIG. 1 is a schematic frame diagram of a heat dissipation apparatus according to an embodiment of the present disclosure. As shown in FIG. 1, the heat dissipation apparatus includes at least one heat dissipation module 100, and each heat dissipation module 100 includes at least two first liquid cooling plates 1 arranged side by side. For example, the at least two first liquid cooling plates 1 are arranged in a row. All first liquid cooling plates 1 in of the same heat dissipation module 100 are connected in series. Each first liquid cooling plate 1 includes a liquid cooling channel 13 with a liquid inlet 11 and a liquid outlet 12. The liquid inlet 11 and the liquid outlet 12 are arranged on a first side of the first liquid cooling plate 1 and are close to two side edges respectively. The first side refers to a side of the first liquid cooling plate 1 in a width direction. Due to the side-by-side arrangement of all first liquid cooling plates 1, in each heat dissipation module 100, the liquid inlets 11 are arranged alternately with the liquid outlets 12. For example, starting from one side of the heat dissipation module 100, the liquid inlet 11, the liquid outlet 12, the liquid inlet 11, and the liquid outlet 12 are arranged in sequence. Therefore, the liquid inlet 11 of one first liquid cooling plate 1 in the adjacent first liquid cooling plates 1 is adjacent to the liquid outlet 12 of the other first liquid cooling plate 1 in the adjacent first liquid cooling plates 1, and thus, a distance between the liquid inlet 11 of one first liquid cooling plate 1 and the liquid outlet 12 of the other first liquid cooling plate 1 is shorter than a distance between the liquid inlet 11 of one first liquid cooling plate 1 and the liquid inlet 11 of the other first liquid cooling plate 1. The liquid inlet 11 of one first liquid cooling plate 1 is closer to the liquid outlet 12 of the adjacent first liquid cooling plate 1 than the liquid inlet 11 of the adjacent first liquid cooling plate 1.

As shown in FIG. 1, in each heat dissipation module 100, the liquid inlet 11 of the first liquid cooling plate 1 at one end is connected to a first liquid inlet pipe 2, the liquid outlet 12 or liquid inlet 11 of the first liquid cooling plate 1 at the other end is connected to a first liquid return pipe 3, and among all the other liquid outlets 12 and liquid inlets 11 in the heat dissipation module 100, two adjacent liquid outlets 12 are connected through a connecting pipe 4, and two adjacent liquid inlets 11 are connected through another connecting pipe 4, thereby forming a staggered connection, i.e., skipping inlet/outlet series connection. The staggered connection and the skipping inlet/outlet series connection mean that one liquid inlet 11 is located between two liquid outlets 12 (non-adjacent) which are connected to two ends of one connecting pipe 4 respectively, or one liquid outlet 12 is located between two liquid inlets 11 (non-adjacent) which are connected to two ends of one connecting pipe 4 respectively. The skipping inlet/outlet series connection between the adjacent first liquid cooling plates 1 in each heat dissipation module 100 increases the bending radii of the connecting pipes 4, reduces the installation complexity between the connecting pipes 4 and the first liquid cooling plates 1, reduces flow resistance, and improves the cooling effect.

Which one of the liquid inlet and the liquid outlet of the first liquid cooling plate 1 at the other end is connected to the first liquid return pipe 3 depends on the number of first liquid cooling plates 1 in each heat dissipation module 100. In some embodiments, the heat dissipation module 100 includes an even number of first liquid cooling plates 1, the first liquid inlet pipe 2 is connected to the liquid inlet 2 of the first liquid cooling plate 1 at one end, the first liquid return pipe 3 is connected to the liquid inlet 11 of the first liquid cooling plate 1 at the other end, and among all the other liquid outlets 12 and liquid inlets 11, staggered connection is implemented between two adjacent liquid outlets 12 through one connecting pipe 4 and between two adjacent liquid inlets 11 through one connecting pipe 4, as shown in FIG. 1. In some embodiments the heat dissipation module 100 includes an odd number of first liquid cooling plates 1, the liquid inlet 11 of the first liquid cooling plate 1 at one end is connected to the first liquid inlet pipe 2, the liquid outlet 12 of the first liquid cooling plate 1 at the other end is connected to the first liquid return pipe 3, and among all the other liquid outlets 12 and liquid inlets 11, staggered connection is implemented between the two adjacent liquid outlets 12 through one connecting pipe 4 and between the two adjacent liquid inlets 11 through one connecting pipe 4, as shown in FIG. 1.

In some embodiments of the present disclosure, the heat dissipation apparatus includes a plurality of heat dissipation modules 100, and the first liquid cooling plates 1 in the heat dissipation module 100 are connected in the staggered series manner as described above to form a loop. The first liquid inlet pipes 2 of the plurality of heat dissipation modules 100 are connected to a cold distribution unit 200 through a first dispenser 9, and the first liquid return pipes 3 of the plurality of heat dissipation modules 100 are connected to the cold distribution unit 200 through a second dispenser 10, to form a plurality of first cooling liquid loops parallel to each other, as shown in FIG. 1. A main liquid inlet pipe 103 is connected between the first dispenser 9 and the cold distribution unit 200, and a main liquid return pipe 104 is connected between the second dispenser 10 and the cold distribution unit 200, as shown in FIG. 1.

The first dispenser 9 and the second dispenser 10 each have a plurality of inlets and outlets, and the first dispenser 9 and the second dispenser 10 are configured to distribute cooling liquid into a plurality of parallel cooling loops. The parallel arrangement of the plurality of first cooling liquid loops indicates that, in the liquid cooling system, the plurality of first cooling liquid loops are independently connected to the same cold distribution unit 200, and each first cooling liquid loop can independently implement cooling without being affected by other loops, thereby effectively improving heat dissipation efficiency. In an another embodiment, the main liquid inlet pipe 103 and the main liquid return pipe 104 may be connected to the cold distribution unit 200 through quick connectors, respectively. The quick connectors are connected to the cold distribution unit 200 in a pluggable manner, making the installation of the heat dissipation apparatus more convenient.

The number of first liquid cooling plates 1 in each heat dissipation module 100 may be the same or different. The number of heat dissipation modules 100 and the number of first liquid cooling plates 1 in each heat dissipation module 100 are determined by the specification of an optical module product. In the embodiments of the present disclosure, “a plurality” refers to two or more. In some embodiments, a plurality of heat dissipation modules 100 are arranged side by side inside an electronic device. The side-by-side arrangement of the plurality of heat dissipation modules 100 indicates an arrangement that the plurality of heat dissipation modules 100 are arranged in the same direction or on a panel inside an electronic device to achieve high-density installation and efficient management, thereby optimizing space utilization inside the device and facilitating later maintenance and upgrade. In addition, the plurality of heat dissipation modules 100 may be arranged at corresponding positions according to specific needs.

As shown in FIG. 1, the heat dissipation apparatus may further include a second liquid cooling plate 105, and the second liquid cooling plate 105 may also be connected to the cold distribution unit 200 through the first dispenser 9 and the second dispenser 10 to form a second cooling liquid loop. The parallel arrangement of the second cooling liquid loop and the first cooling liquid loops improves heat dissipation efficiency. For example, the first dispenser 9 is connected to the second liquid cooling plate 105 through a second liquid inlet pipe 101, and the second dispenser 10 is connected to the second liquid cooling plate 105 through a second liquid return pipe 102. Cooling liquid flows out from the cold distribution unit 200 to the second liquid inlet pipe 101 via the main liquid inlet pipe 103 and the first dispenser 9, then flows into the second liquid cooling plate 105, then flows out from the second liquid cooling plate 105 to the second dispenser 10 via the second liquid return pipe 102, and returns to the cold distribution unit 200 via the main liquid return pipe 104.

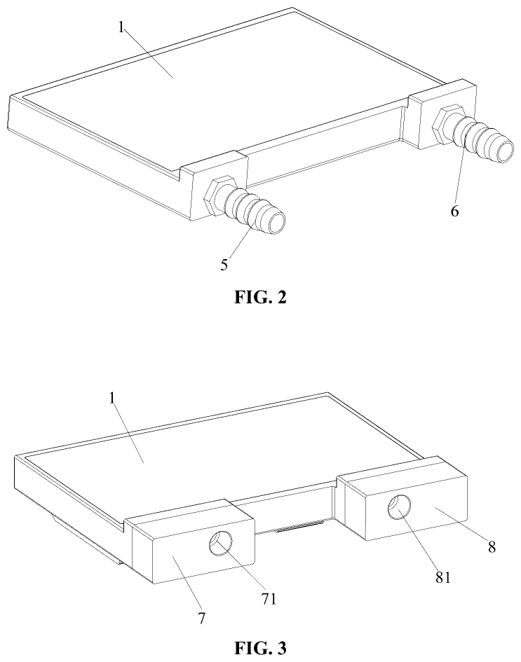

In one embodiment, a liquid inlet connector 5 is installed at the liquid inlet 11 of the first liquid cooling plate 1, and a liquid outlet connector 6 is installed at the liquid outlet 12, as shown in FIG. 2. The liquid inlet connector 5 and the liquid outlet connector 6 are directly connected to the first liquid inlet pipe 2, the first liquid return pipe 3, or the connecting pipe 4, respectively. The liquid inlet connector 5 and the liquid outlet connector 6 do not change the flow direction of the cooling liquid. The liquid inlet connector 5 and the liquid outlet connector 6 are used to ensure that the connection between the pipeline and the first liquid cooling plate 1 is fast and reliable, prevent leakage, and ensure long-term stable operation of the system. Common types of the liquid inlet connector 5 and the liquid outlet connector 6 include quick plug connectors, threaded connectors, sleeve connectors, crimping connectors, and flange connectors. The selection of connectors depends on the type of cooling liquid, working pressure, temperature range, connection frequency, etc. The second liquid cooling plate 105, the first dispenser 9, the second dispenser 10, etc. may also be connected to the pipeline through the above connectors.

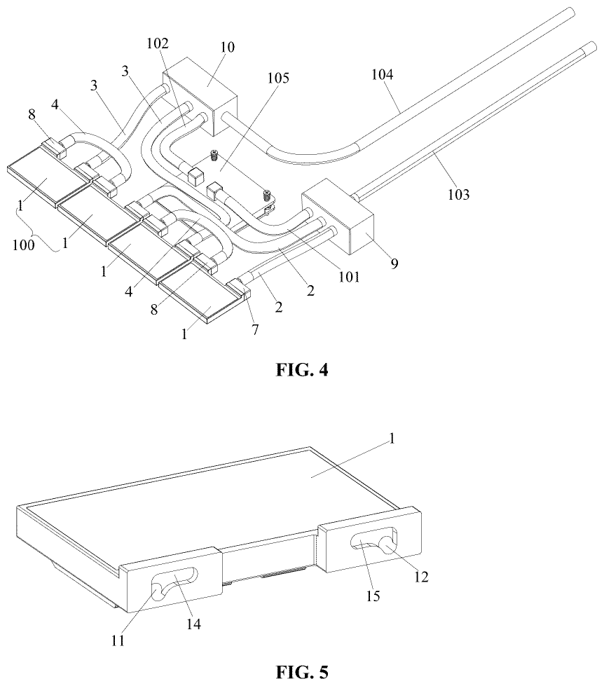

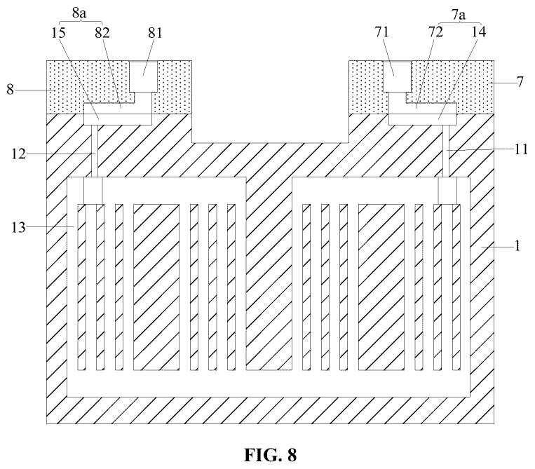

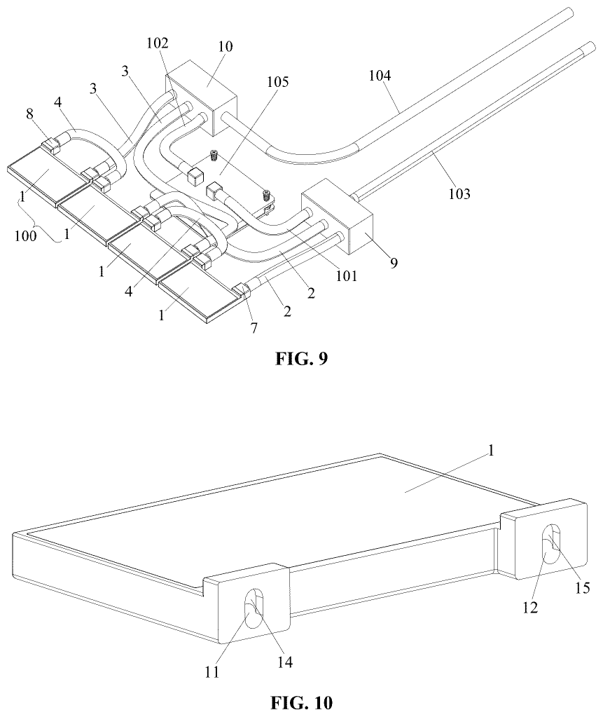

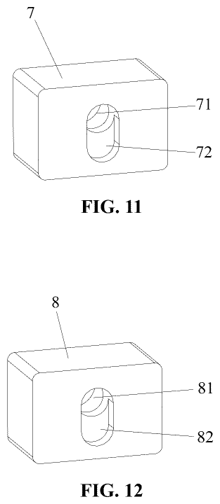

In another embodiment, a first connection block 7 is installed at the liquid inlet 11 of the first liquid cooling plate 1, and a second connection block 8 is installed at the liquid outlet 12 of the first liquid cooling plate 1, as shown in FIG. 3, FIG. 4, and FIG. 9. The first connection block 7 is provided with a first installation hole 71, and the second connection block 8 is provided with a second installation hole 81, as shown in FIG. 3, FIG. 11, and FIG. 12. After the first connection block 7 is connected to the liquid inlet 11 of the first liquid cooling plate 1, a first guide channel 7a is formed between the first connection block 7 and the first liquid cooling plate 1. The first installation hole 71 and the liquid inlet 11 are connected to two end openings of the first guide channel 7a respectively in such a manner that the first installation hole 71 and the liquid inlet 11 are staggered without facing each other, as shown in FIG. 8. For example, the first installation hole 71 and the liquid inlet 11 are vertically connected to the first guide channel 7a, respectively. The first installation hole 71 is connected to the corresponding pipeline through a connector. After the second connection block 8 is connected to the liquid outlet 12 of the first liquid cooling plate 1, a second guide channel 8a is formed between the second connection block 8 and the first liquid cooling plate 1. The second installation hole 81 and the liquid outlet 12 are connected to two end openings of the second guide channel 8a respectively in such a manner that the second installation hole 81 and the liquid outlet 12 are staggered without facing each other, as shown in FIG. 8. For example, the second installation hole 81 and the liquid outlet 12 are vertically connected to the second guide channel 8a, respectively. The second installation hole 81 is connected to the corresponding pipeline through a connector. The first guide channel 7a and the second guide channel 8a are smooth channels for reducing the flow resistance of the cooling liquid, and their smoothness can be designed as required.

The expression “the first installation hole 71 and the liquid inlet 11 are staggered without facing each other” indicates that the first installation hole 71 and the liquid inlet 11 may be staggered vertically (i.e., height direction/up and down) and/or horizontally (i.e., length direction/left and right), so that the first installation hole 71 and the liquid inlet 11 do not face each other. The expression “the second installation hole 81 and the liquid outlet 12 are staggered without facing each other” indicates that the second installation hole 81 and the liquid outlet 12 may be staggered vertically (i.e., height direction/up and down) and/or horizontally (i.e., length direction/left and right), so that the second installation hole 81 and the liquid outlet 12 do not face each other.

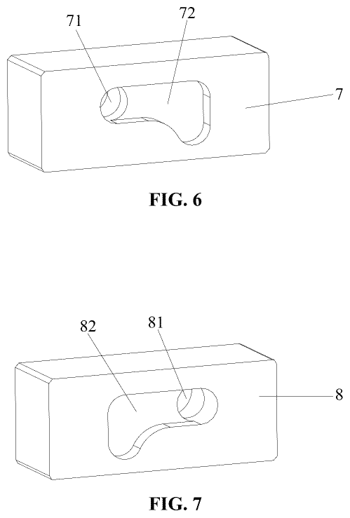

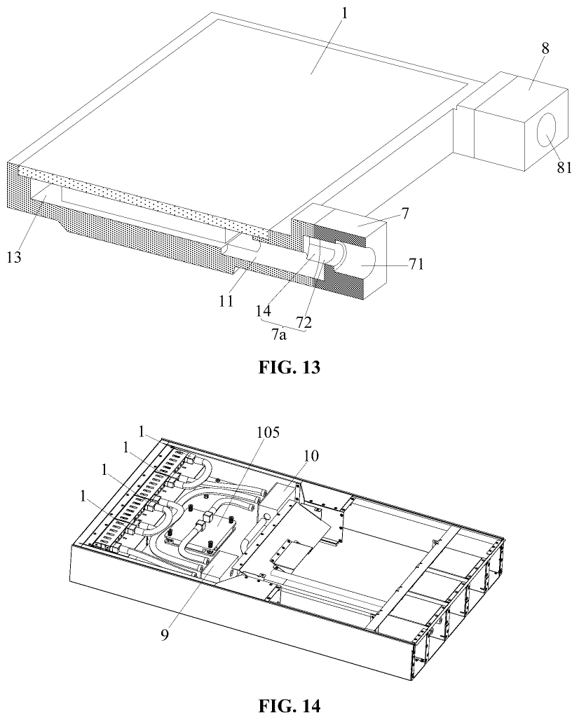

In the embodiments of the present disclosure, the first liquid cooling plate 1 is provided with a first fluid groove 14, the first fluid groove 14 is located outside the liquid inlet 11, and the liquid inlet 11 is connected to one end of the first fluid groove 14, as shown in FIG. 5 and FIG. 10. The first liquid cooling plate 1 is further provided with a third fluid groove 15, the third fluid groove 15 is located outside the liquid outlet 12, and the liquid outlet 12 is connected to one end of the third fluid groove 15, as shown in FIG. 5 and FIG. 10. The first connection block 7 is provided with a second fluid groove 72, the second fluid groove 72 is located on one side of the first installation hole 71, and one end of the second fluid groove 72 is connected to the first installation hole 71, as shown in FIG. 6 and FIG. 11. The second connection block 8 is provided with a fourth fluid groove 82, the fourth fluid groove 82 is located on one side of the second installation hole 81, and one end of the fourth fluid groove 82 is connected to the second installation hole 81, as shown in FIG. 7 and FIG. 12. The first fluid groove 14 and the second fluid groove 72 are symmetrical, and the third fluid groove 15 and the fourth fluid groove 82 are symmetrical. After the first connection block 7, the second connection block 8, and the first liquid cooling plate 1 are connected, the first fluid groove 14 and the second fluid groove 72 face each other and are connected to form the first guide channel 7a, and the third fluid groove 15 and the fourth fluid groove 82 face each other and are connected to form the second guide channel 8a, as shown in FIG. 8 and FIG. 13. The formation method of the first guide channel 7a and the second guide channel 8a facilitates processing and operation.

In one embodiment, the first guide channel 7a and the second guide channel 8a extend along a height or length direction, so that the first installation hole 71 and the liquid inlet 11 are staggered along the height or length direction (horizontal direction) without facing each other, and the second installation hole 81 and the liquid outlet 12 are staggered along the height or length direction without facing each other. FIG. 10 to FIG. 12 are schematic structural diagrams of the first liquid cooling plate, the first connection block 7, and the second connection block 8, respectively. As shown in FIG. 10 to FIG. 12, the first fluid groove 14, the third fluid groove 15, the second fluid groove 72, and the fourth fluid groove 82 extend along the height direction. FIG. 13 is a schematic diagram showing that the first guide channel 7a and the second guide channel 8a extend along the height direction. As shown in FIG. 13, the first installation hole 71 and the liquid inlet 11 are staggered along the height direction. The extension structures of the first guide channel 7a and the second guide channel 8a along the length direction are not shown, but are substantially similar to the foregoing embodiment. The first installation hole 71 and the liquid inlet 11, as well as the second installation hole 81 and the liquid outlet 12, are staggered along the length direction or the height direction, depending on the space in front of the first liquid cooling plate.

In another embodiment, the first guide channel 7a and the second guide channel 8a are L-shaped channels or obliquely extending channels, so that the first installation hole 71 and the liquid inlet 11 are obliquely staggered without facing each other, and the second installation hole 81 and the liquid outlet 12 are obliquely staggered without facing each other. The expression “obliquely staggered without facing each other” includes obliquely upward or downward staggered, indicating that the two are staggered in both the height direction and the horizontal direction. Such arrangement can meet the requirements of installation space. FIG. 5 to FIG. 7 are schematic structural diagrams of the first liquid cooling plate, the first connection block 7, and the second connection block 8, respectively. As shown in FIG. 5 to FIG. 7, each of the first fluid groove 14, the third fluid groove 15, the second fluid groove 72, and the fourth fluid groove 82 is a L-shaped groove, and two ends of the L-shaped groove are staggered in both the height direction and the length direction.

In the heat dissipation apparatus according to the embodiments of the present disclosure, the heat dissipation module includes at least two first liquid cooling plates arranged side by side and connected in series, the liquid inlet of the first liquid cooling plate at one end is connected to the first liquid inlet pipe, the liquid outlet or liquid inlet of the first liquid cooling plate at the other end is connected to the first liquid return pipe, and among all the other liquid outlets and liquid inlets, two adjacent liquid outlets are connected through a connecting pipe, two adjacent liquid inlets are connected through another connecting pipe, thereby increasing the bending radii and operability of the connecting pipes, reducing flow resistance, and improving heat dissipation capacity.

FIG. 14 is a schematic structural diagram of an electronic device according to an embodiment of the present disclosure. The electronic device includes a chassis and the heat dissipation apparatus of the foregoing embodiments. Optical module groups are provided in the chassis. Each optical module group may include a plurality of optical modules. The heat dissipation apparatus may be installed in the chassis to dissipate heat for heat generating components in the chassis. The number of first liquid cooling plates 1 in the heat dissipation apparatus is the same as the number of optical module groups. Each optical module group is connected to a corresponding one first liquid cooling plate 1, and the corresponding one first liquid cooling plate 1 is above the optical module group. Therefore, heat dissipation capacity is improved through liquid cooling.

In some embodiments, the plurality of optical module groups may be arranged side by side at one end of the chassis, and the plurality of first liquid cooling plates may be installed side by side above the corresponding optical module groups, thereby fully utilizing the space utilization of the chassis and effectively reducing the temperature in the chassis. The optical module groups are installed side by side in corresponding shielding cages. The first liquid cooling plates 1 are above the corresponding shielding cages and are fastened to the shielding cages through a fastening structure, thereby dissipating heat for the optical modules in the shielding cages. The fastening structure includes a first fastening member and a second fastening member that are fastened in an up-down direction to form an accommodating space. The first fastening member is further be fastened with the shielding cage, the first liquid cooling plate 1 is installed in the accommodating space, and thus these elements form a whole, thereby facilitating disassembly and installation.

Electronic components, such as a processor, a chip, and a circuit board are arranged in the chassis. The second liquid cooling plate 105 in the heat dissipation apparatus is connected to the electronic components for dissipating heat for the electronic components. In the present disclosure, the interior of the chassis is partitioned into an upper space and a lower space through a partition plate. The heat dissipation apparatus may be arranged in the upper space, so that the heat dissipation apparatus can be small and thin and can be easily installed in an electronic device with high-density electronic components, and the entire electronic device is thin and small. The lower space of the chassis may be provided with a fan light heat dissipation structure, which can dissipate heat for other electronic components inside the chassis.

In the heat dissipation apparatus of the electronic device according to the embodiments of the present disclosure, the skipping inlet/outlet series connection between the adjacent first liquid cooling plates through the connecting pipes increases the bending radii of the connecting pipes and operability, reduces flow resistance, and improves heat dissipation capacity.

Described above are merely the preferred embodiments of the present disclosure, and the present disclosure is not limited thereto. Various modifications and variations may be made to the present disclosure for those skilled in the art. Any modifications, equivalent substitutions, improvements, and the like made within the spirit and principle of the present disclosure shall fall within the protection scope of the present disclosure.

What is claimed is:

1. A heat dissipation apparatus, comprising at least one set heat dissipation module, wherein each heat dissipation module comprises at least two first liquid cooling plates arranged side by side and connected in series, each first liquid cooling plate comprises a liquid cooling channel with a liquid inlet and a liquid outlet, the liquid inlet and the liquid outlet are arranged on a first side of the first liquid cooling plate and are close to two side edges respectively, and the liquid inlet of one of the at least two first liquid cooling plates is adjacent to the liquid outlet of the an adjacent one of the at least two first liquid cooling plates;
wherein the at least two first liquid cooling plates arranged side by side in the heat dissipation module comprise a first liquid cooling plate at one end and a first liquid cooling plate at the other end, the liquid inlet of the first liquid cooling plate at one end is connected to a first liquid inlet pipe, the liquid outlet or liquid inlet of the first liquid cooling plate at the other end is connected to a first liquid return pipe, and for all other liquid outlets and liquid inlets of the at least two first liquid cooling plates, two adjacent liquid outlets are connected through a connecting pipe, two adjacent liquid inlets are connected through another connecting pipe.

2. The heat dissipation apparatus according to claim 1, wherein the heat dissipation module comprises an even number of first liquid cooling plates, the liquid inlet of the first liquid cooling plate at one end is connected to the first liquid inlet pipe, the liquid inlet of the first liquid cooling plate at the other end is connected to the first liquid return pipe, and for all other liquid outlets and liquid inlets of the at least two first liquid cooling plates, two adjacent liquid outlets are connected through a connecting pipe, two adjacent liquid inlets are connected through another connecting pipe.

3. The heat dissipation apparatus according to claim 1, wherein the heat dissipation module comprises an odd number of first liquid cooling plates, the liquid inlet of the first liquid cooling plate at one end is connected to the first liquid inlet pipe, the liquid outlet of the first liquid cooling plate at the other end is connected to the first liquid return pipe, and for all other liquid outlets and liquid inlets of the at least two first liquid cooling plates, two adjacent liquid outlets are connected through a connecting pipe, two adjacent liquid inlets are connected through another connecting pipe.

4. The heat dissipation apparatus according to claim 1, wherein a liquid inlet connector is installed at the liquid inlet, a liquid outlet connector is installed at the liquid outlet, and the liquid inlet connector and the liquid outlet connector are connected to one of the first liquid inlet pipe, the first liquid return pipe, or the connecting pipe.

5. The heat dissipation apparatus according to claim 1, wherein a first connection block is installed outside the liquid inlet, the first connection block is provided with a first installation hole, a first guide channel is formed between the first connection block and the first liquid cooling plate, the first installation hole and the liquid inlet are connected to two end openings of the first guide channel respectively, and the first installation hole and the liquid inlet are staggered without facing each other; and
a second connection block is installed outside the liquid outlet, the second connection block is provided with a second installation hole, a second guide channel is formed between the second connection block and the first liquid cooling plate, the second installation hole and the liquid outlet are connected to two end openings of the second guide channel respectively, and the second installation hole and the liquid outlet are staggered without facing each other.

6. The heat dissipation apparatus according to claim 5, wherein the first guide channel and the second guide channel extend along a height or length direction, the first installation hole and the liquid inlet are staggered along the height or length direction without facing each other, and the second installation hole and the liquid outlet are staggered along the height or length direction without facing each other.

7. The heat dissipation apparatus according to claim 5, wherein the first guide channel and the second guide channel are L-shaped channels or obliquely extending channels, the first installation hole and the liquid inlet are obliquely staggered without facing each other, and the second installation hole and the liquid outlet are obliquely staggered without facing each other.

8. The heat dissipation apparatus according to claim 5, wherein the first liquid cooling plate is provided with a first fluid groove, the first fluid groove is located outside the liquid inlet, and the liquid inlet is connected to one end of the first fluid groove;
the first connection block is provided with a second fluid groove, the second fluid groove is located on one side of the first installation hole, one end of the second fluid groove is connected to the first installation hole, and the first fluid groove and the second fluid groove face each other and are connected to form the first guide channel; and
the first liquid cooling plate is provided with a third fluid groove, the third fluid groove is located outside the liquid outlet, and the liquid outlet is connected to one end of the third fluid groove; the second connection block is provided with a fourth fluid groove, the fourth fluid groove is located on one side of the second installation hole, and one end of the fourth fluid groove is connected to the second installation hole; and the third fluid groove and the fourth fluid groove face each other and are connected to form the second guide channel.

9. The heat dissipation apparatus according to claim 8, wherein the first connection block comprises a first surface and a second surface opposite to the first surface, the second surface is in contact with a surface of the first liquid cooling plate where the first fluid groove is formed, the first installation hole is formed at the first surface of the first connection block, and the second fluid groove is formed at the second surface of the first connection block,
the second connection block comprises a first surface and a second surface opposite to the first surface, the second surface is in contact with a surface of the first liquid cooling plate where the third fluid groove is formed, the second installation hole is formed at the first surface of the second connection block, and the fourth fluid groove is formed at the second surface of the second connection block.

10. The heat dissipation apparatus according to claim 1, wherein the at least one set heat dissipation module comprises a plurality of heat dissipation modules arranged side by side, the first liquid inlet pipes of the plurality of heat dissipation modules are connected to a first dispenser, the first liquid return pipes of the plurality of heat dissipation modules are connected to a second dispenser, the first dispenser and the second dispenser are connected to a cold distribution unit to form a plurality of parallel first cooling liquid loops corresponding to the plurality of heat dissipation modules.

11. The heat dissipation apparatus according to claim 10, further comprising a second liquid cooling plate, wherein the second liquid cooling plate comprises a second liquid inlet pipe and a second liquid return pipe, the second liquid inlet pipe and the second liquid return pipe of the second liquid cooling plate are connected to the cold distribution unit through the first dispenser and the second dispenser respectively to form a second cooling liquid loop, and the second cooling liquid loop is arranged in parallel to the first cooling liquid loops.

12. The heat dissipation apparatus according to claim 11, wherein a main liquid inlet pipe is connected between the first dispenser and the cold distribution unit, and a main liquid return pipe is connected between the second dispenser and the cold distribution unit.

13. The heat dissipation apparatus according to claim 1, wherein, in a plan view, the connecting pipe extends intersecting with the another connecting pipe.

14. A heat dissipation apparatus, comprising at least one set heat dissipation module, a first dispenser, and a second dispenser,
wherein each heat dissipation module comprises two first liquid cooling plates arranged side by side, each first liquid cooling plate comprises a liquid cooling channel with a liquid inlet and a liquid outlet, and the liquid inlet and the liquid outlet are arranged on a side of the first liquid cooling plate facing the first dispenser and the second dispenser,
wherein the liquid inlet of one of the two first liquid cooling plates is connected to the first dispenser via a first liquid inlet pipe, the liquid outlet of one of the two first liquid cooling plates is connected to the liquid outlet of the other one of the two first liquid cooling plates via a connecting pipe, and the liquid inlet of the other one of the two first liquid cooling plates is connected to the second dispenser via a first liquid return pipe,
the liquid outlet of the one of the two first liquid cooling plates is closer to the other one of the two first liquid cooling plates than the liquid inlet of the one of the two first liquid cooling plates.

15. The heat dissipation apparatus according to claim 14, wherein, in a plan view, the connecting pipe extends intersecting with the first liquid return pipe.

16. An electronic device, comprising a chassis and a heat dissipation apparatus,
wherein the heat dissipation apparatus comprises at least one set heat dissipation module, each heat dissipation module comprises at least two first liquid cooling plates arranged side by side and connected in series, each first liquid cooling plate comprises a liquid cooling channel with a liquid inlet and a liquid outlet, the liquid inlet and the liquid outlet are arranged on a first side of the first liquid cooling plate and are close to two side edges respectively, and the liquid inlet of one of the at least two first liquid cooling plates is adjacent to the liquid outlet of the an adjacent one of the at least two first liquid cooling plates;
wherein the at least two first liquid cooling plates arranged side by side in the heat dissipation module comprise a first liquid cooling plate at one end and a first liquid cooling plate at the other end, the liquid inlet of the first liquid cooling plate at one end is connected to a first liquid inlet pipe, the liquid outlet or liquid inlet of the first liquid cooling plate at the other end is connected to a first liquid return pipe, and for all other liquid outlets and liquid inlets of the at least two first liquid cooling plates, two adjacent liquid outlets are connected through a connecting pipe, two adjacent liquid inlets are connected through another connecting pipe;
wherein at least two optical module groups are arranged in the chassis, and the first liquid cooling plates are connected to the at least two optical module groups in one-to-one correspondence.

17. The electronic device according to claim 16, wherein the heat dissipation apparatus further comprises a second liquid cooling plate arranged in parallel to a first cooling liquid loop of the heat dissipation module, the electronic device further comprises electronic components, and the second liquid cooling plate is connected to the electronic components.

18. The electronic device according to claim 16, further comprising a shielding cage and a fastening structure arranged above the shielding cage, the fastening structure comprises a first fastening member and a second fastening member, the first fastening member and the second fastening member are fastened in an up-down direction to form an accommodating space, the first fastening member is fastened with the shielding cage, the first liquid cooling plate is installed in the accommodating space, and the optical module group is installed in the shielding cage.

19. The electronic device according to claim 16, wherein the heat dissipation module comprises an even number of first liquid cooling plates, the liquid inlet of the first liquid cooling plate at one end is connected to the first liquid inlet pipe, the liquid inlet of the first liquid cooling plate at the other end is connected to the first liquid return pipe, and for all other liquid outlets and liquid inlets of the at least two first liquid cooling plates, two adjacent liquid outlets are connected through a connecting pipe, two adjacent liquid inlets are connected through another connecting pipe.

20. The electronic device according to claim 16, wherein the heat dissipation module comprises an odd number of first liquid cooling plates, the liquid inlet of the first liquid cooling plate at one end is connected to the first liquid inlet pipe, the liquid outlet of the first liquid cooling plate at the other end is connected to the first liquid return pipe, and for all other liquid outlets and liquid inlets of the at least two first liquid cooling plates, two adjacent liquid outlets are connected through a connecting pipe, two adjacent liquid inlets are connected through another connecting pipe.
